(19) United States
(12) Patent Application Publication
(10) Pub. No.: US 2025/0080085 A1
(43) Pub. Date: Mar. 6, 2025

(54) ACOUSTIC WAVE FILTER MODULES WITH INTEGRATED PHASE SHIFT CIRCUITS

(71) Applicant: Skyworks Solutions, Inc., Irvine, CA (US)

(72) Inventor: Akira Ochiai, Suita-Shi (JP)

(21) Appl. No.: 18/812,838

(22) Filed: Aug. 22, 2024

Related U.S. Application Data
(60) Provisional application No. 63/534,938, filed on Aug. 28, 2023.

(51) Int. Cl. H03H 9/64; H03H 9/02; H03H 9/145; H04B 1/00; H04B 1/44

(52) U.S. Cl. CPC H03H 9/64; H03H 9/02559; H03H 9/145; H04B 1/006; H04B 1/44

(57) ABSTRACT

An acoustic wave filter module has a piezoelectric substrate mounted on a metal plate, with a surface acoustic wave filter mounted on the piezoelectric substrate and coupled between a first input and an output of the acoustic wave filter module. A capacitor is mounted on the piezoelectric substrate and two inductors are formed on the metal plate. The two inductors and the capacitor electrically implement a π-type high pass filter coupled between the surface acoustic wave filter and an output of the acoustic wave filter module.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

### BACKGROUND

### Field

Embodiments of the invention relate to electronic systems, and in particular, to radio frequency electronics.

### Description of Related Technology

Radio frequency (RF) communication systems can be used for transmitting and/or receiving signals of a wide range of frequencies. For example, an RF communication system can be used to wirelessly communicate RF signals in a frequency range of about 30 kHz to 300 GHz, such as in the range of about 410 MHz to about 7.125 GHz for fifth generation (5G) frequency range 1 (FR1) communications and in the range of about 24.25 GHz to about 52.6 GHz for 5G frequency range 2 (FR2) communications.

Examples of RF communication systems include, but are not limited to, mobile phones, tablets, base stations, network access points, customer-premises equipment (CPE), laptops, and wearable electronics.

### SUMMARY

In certain embodiments, the present disclosure relates to an acoustic wave filter module. The acoustic wave filter includes a metal plate, a piezoelectric substrate mounted on the metal plate, a first surface acoustic wave (SAW) filter mounted on the piezoelectric substrate and coupled between a first input and an output of the acoustic wave filter module, a capacitor mounted on the piezoelectric substrate, and two inductors formed on the metal plate. The two inductors and the capacitor are electrically connected to implement a π-type high pass filter coupled between the first SAW filter and the output of the acoustic wave filter module. Additional inductors and/or capacitors can be included in some embodiments.

In some embodiments, the piezoelectric substrate is a lithium tantalate or lithium niobate substrate. According to a number of embodiments, the metal plate is a copper plate.

In several embodiments, the π-type high pass filter induces a phase shift of a radio frequency (RF) signal filtered by the first SAW filter.

In various embodiments, the two inductors have the same inductivity.

In some embodiments, the acoustic wave filter further comprises a second SAW filter coupled in parallel to the first SAW filter between a second input and the output of the acoustic wave filter module. In several embodiments, the π-type high pass filter is configured to reduce the reflection coefficient at the output of the first SAW filter in the passband of the second SAW filter.

In certain embodiments, the present disclosure relates to a multi-chip module (MCM) for a mobile device. The MCM includes a first die including an acoustic wave filter module. The acoustic wave filter module includes a metal plate, a piezoelectric substrate mounted on the metal plate, a first surface acoustic wave (SAW) filter mounted on the piezoelectric substrate and coupled between a first input and an output of the acoustic wave filter module, a capacitor mounted on the piezoelectric substrate, and two inductors formed on the metal plate. The two inductors and the capacitor are electrically connected to implement a π-type high pass filter coupled between the first SAW filter and the output of the acoustic wave filter module. The MCM further includes a second die including an antenna switch module (ASM) coupled to the output of the acoustic wave filter module. The MCM further includes a third die including a power amplifier module coupled to an input of the acoustic wave filter module. Additional inductors and/or capacitors can be included in some embodiments.

In various embodiments, the piezoelectric substrate is a lithium tantalate or lithium niobate substrate. In some embodiments, the metal plate is a copper plate.

In some embodiments, the π-type high pass filter induces a phase shift of a radio frequency (RF) signal filtered by the first SAW filter.

In several embodiments, the acoustic wave filter module further includes a second SAW filter coupled in parallel to the first SAW filter between a second input and the output of the acoustic wave filter module. In various embodiments, the π-type high pass filter is configured to reduce the reflection coefficient at the output of the first SAW filter in the passband of the second SAW filter.

In certain embodiments, the present disclosure relates to a mobile device. The mobile device includes an antenna configured to receive and transmit radio frequency (RF) signals. The mobile device further includes a front end module (FEM) including an antenna switch module (ASM) electrically connected to an acoustic wave filter module, the acoustic wave filter module including a metal plate, a piezoelectric substrate mounted on the metal plate, a first surface acoustic wave (SAW) filter mounted on the piezoelectric substrate and coupled between a first input and an output of the acoustic wave filter module, a capacitor mounted on the piezoelectric substrate, and two inductors formed on the metal plate. The two inductors and the capacitor are electrically connected to implement a π-type high pass filter coupled between the first SAW filter and the output of the acoustic wave filter module. The mobile device further includes a transceiver coupled to the FEM and configured to process RF signals received or transmitted by the antenna. Additional inductors and/or capacitors can be included in some embodiments.

In various embodiments, the mobile device is a smartphone.

In some embodiments, the FEM further includes a power amplifier module including power amplifiers configured to amplify RF signals received from the transceiver.

In several embodiments, the piezoelectric substrate is a lithium tantalate or lithium niobate substrate. In various embodiments, the metal plate is a copper plate.

According to a number of embodiments, the π-type high pass filter induces a phase shift of a radio frequency (RF) signal filtered by the first SAW filter.

In various embodiments, the two inductors have the same inductivity.

In some embodiments, the acoustic wave filter module further includes a second SAW filter coupled in parallel to the first SAW filter between a second input and the output of the acoustic wave filter module. In several embodiments, the π-type high pass filter is configured to reduce the reflection coefficient at the output of the first SAW filter in the passband of the second SAW filter.

### BRIEF DESCRIPTION OF THE DRAWINGS

Embodiments of this disclosure will now be described, by way of non-limiting example, with reference to the accompanying drawings.

FIG. 1 is a schematic diagram of one example of a communication network.

FIG. 2A is a schematic diagram of one example of a communication link using carrier aggregation.

FIG. 2B illustrates various examples of uplink carrier aggregation for the communication link of FIG. 2A.

FIG. 2C illustrates various examples of downlink carrier aggregation for the communication link of FIG. 2A.

FIG. 3A is a schematic diagram of one example of a downlink channel using multi-input and multi-output (MIMO) communications.

FIG. 3B is schematic diagram of one example of an uplink channel using MIMO communications.

FIG. 3C is schematic diagram of another example of an uplink channel using MIMO communications.

FIG. 4A is a schematic diagram of one embodiment of a front-end module supporting carrier aggregation.

FIG. 4B is a schematic diagram of another embodiment of a front-end module supporting carrier aggregation.

FIG. 5 is a schematic diagram of an exemplary wireless communication configuration for uplink and/or downlink carrier aggregation using front-end modules for particular ranges of cellular frequency bands.

FIG. 6A is a schematic diagram of a front-end module supporting carrier aggregation according to one embodiment.

FIG. 6B is a schematic diagram of a front-end module supporting carrier aggregation according to another embodiment.

FIG. 7A is a schematic diagram of an exemplary network of two acoustic wave filters in a front-end module.

FIG. 7B is a representation of S11 parameters in a Smith chart for the exemplary network of the two acoustic wave filters in FIG. 7A.

FIG. 8 is a schematic diagram of an acoustic wave filter with an integrated phase shift circuit according to an embodiment.

FIG. 9A is a simplified plan view of an example of a surface acoustic wave resonator.

FIG. 9B is a simplified plan view of another example of a surface acoustic wave resonator.

FIG. 9C is a simplified plan view of another example of a surface acoustic wave resonator.

FIG. 10 is a cross-sectional view of a portion of a surface acoustic wave resonator having a piezoelectric substrate.

FIG. 11 illustrates an example wireless device having one or more advantageous features described herein.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the claims. In this description, reference is made to the drawings in which like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

The International Telecommunication Union (ITU) is a specialized agency of the United Nations (UN) responsible for global issues concerning information and communication technologies, including the shared global use of radio spectrum.

The 3rd Generation Partnership Project (3GPP) is a collaboration between groups of telecommunications standard bodies across the world, such as the Association of Radio Industries and Businesses (ARIB), the Telecommunications Technology Committee (TTC), the China Communications Standards Association (CCSA), the Alliance for Telecommunications Industry Solutions (ATIS), the Telecommunications Technology Association (TTA), the European Telecommunications Standards Institute (ETSI), and the Telecommunications Standards Development Society, India (TSDSI).

Working within the scope of the ITU, 3GPP develops and maintains technical specifications for a variety of mobile communication technologies, including, for example, second generation (2G) technology (for instance, Global System for Mobile Communications (GSM) and Enhanced Data Rates for GSM Evolution (EDGE)), third generation (3G) technology (for instance, Universal Mobile Telecommunications System (UMTS) and High Speed Packet Access (HSPA)), and fourth generation (4G) technology (for instance, Long Term Evolution (LTE) and LTE-Advanced).

The technical specifications controlled by 3GPP can be expanded and revised by specification releases, which can span multiple years and specify a breadth of new features and evolutions.

In one example, 3GPP introduced carrier aggregation (CA) for LTE in Release 10. Although initially introduced with two downlink carriers, 3GPP expanded carrier aggregation in Release 14 to include up to five downlink carriers and up to three uplink carriers. Other examples of new features and evolutions provided by 3GPP releases include, but are not limited to, License Assisted Access (LAA), enhanced LAA (eLAA), Narrowband Internet of things (NB-IoT), Vehicle-to-Everything (V2X), and High Power User Equipment (HPUE).

3GPP introduced Phase 1 of fifth generation (5G) technology in Release 15, and plans to introduce Phase 2 of 5G technology in Release 16 (targeted for 2019). Subsequent 3GPP releases will further evolve and expand 5G technology. 5G technology is also referred to herein as 5G New Radio (NR).

5G NR supports or plans to support a variety of features, such as communications over millimeter wave spectrum, beamforming capability, high spectral efficiency waveforms, low latency communications, multiple radio numerology, and/or non-orthogonal multiple access (NOMA). Although such RF functionalities offer flexibility to networks and enhance user data rates, supporting such features can pose a number of technical challenges.

The teachings herein are applicable to a wide variety of communication systems, including, but not limited to, communication systems using advanced cellular technologies, such as LTE-Advanced, LTE-Advanced Pro, and/or 5G NR.

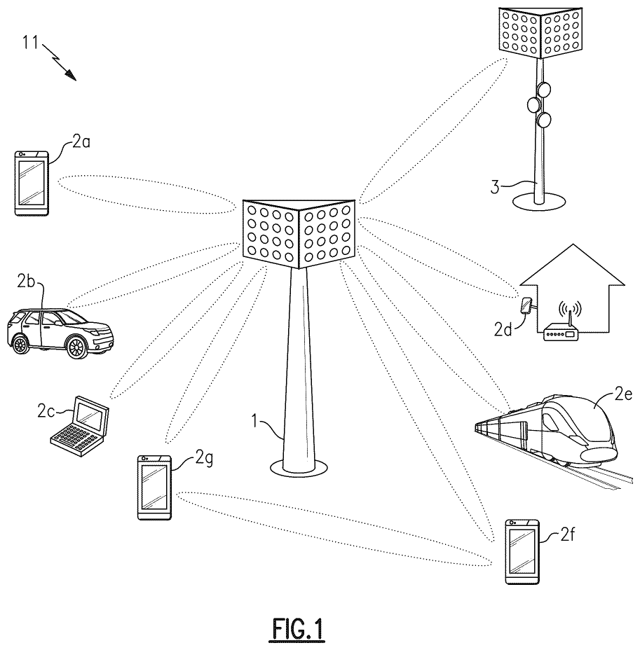

FIG. 1 is a schematic diagram of one example of a communication network 11. The communication network 11 includes a macro cell base station 1, a small cell base station 3, and various examples of user equipment (UE), including a first mobile device 2a, a wireless-connected car 2b, a laptop 2c, a stationary wireless device 2d, a wireless-connected train 2e, a second mobile device 2f, and a third mobile device 2g.

Although specific examples of base stations and user equipment are illustrated in FIG. 1, a communication network can include base stations and user equipment of a wide variety of types and/or numbers.

For instance, in the example shown, the communication network 11 includes the macro cell base station 1 and the small cell base station 3. The small cell base station 3 can operate with relatively lower power, shorter range, and/or with fewer concurrent users relative to the macro cell base station 1. The small cell base station 3 can also be referred to as a femtocell, a picocell, or a microcell. Although the communication network 11 is illustrated as including two base stations, the communication network 11 can be implemented to include more or fewer base stations and/or base stations of other types.

Although various examples of user equipment are shown, the teachings herein are applicable to a wide variety of user equipment, including, but not limited to, mobile phones, tablets, laptops, IoT devices, wearable electronics, customer premises equipment (CPE), wireless-connected vehicles, wireless relays, and/or a wide variety of other communication devices. Furthermore, user equipment includes not only currently available communication devices that operate in a cellular network, but also subsequently developed communication devices that will be readily implementable with the inventive systems, processes, methods, and devices as described and claimed herein.

The illustrated communication network 11 of FIG. 1 supports communications using a variety of cellular technologies, including, for example, 4G LTE and 5G NR. In certain implementations, the communication network 11 is further adapted to provide a wireless local area network (WLAN), such as WiFi. Although various examples of communication technologies have been provided, the communication network 10 can be adapted to support a wide variety of communication technologies.

Various communication links of the communication network 11 have been depicted in FIG. 1. The communication links can be duplexed in a wide variety of ways, including, for example, using frequency-division duplexing (FDD) and/or time-division duplexing (TDD). FDD is a type of radio frequency communications that uses different frequencies for transmitting and receiving signals. FDD can provide a number of advantages, such as high data rates and low latency. In contrast, TDD is a type of radio frequency communications that uses about the same frequency for transmitting and receiving signals, and in which transmit and receive communications are switched in time. TDD can provide a number of advantages, such as efficient use of spectrum and variable allocation of throughput between transmit and receive directions.

In certain implementations, user equipment can communicate with a base station using one or more of 4G LTE, 5G NR, and WiFi technologies. In certain implementations, enhanced license assisted access (eLAA) is used to aggregate one or more licensed frequency carriers (for instance, licensed 4G LTE and/or 5G NR frequencies), with one or more unlicensed carriers (for instance, unlicensed WiFi frequencies).

As shown in FIG. 1, the communication links include not only communication links between UE and base stations, but also UE to UE communications and base station to base station communications. For example, the communication network 11 can be implemented to support self-fronthaul and/or self-backhaul (for instance, as between mobile device 2g and mobile device 2f).

The communication links can operate over a wide variety of frequencies. In certain implementations, communications are supported using 5G NR technology over one or more frequency bands that are less than 6 Gigahertz (GHz) and/or over one or more frequency bands that are greater than 6 GHz. For example, the communication links can serve Frequency Range 1 (FR1), Frequency Range 2 (FR2), or a combination thereof. In one embodiment, one or more of the mobile devices support a HPUE power class specification.

In certain implementations, a base station and/or user equipment communicates using beamforming. For example, beamforming can be used to focus signal strength to overcome path losses, such as high loss associated with communicating over high signal frequencies. In certain embodiments, user equipment, such as one or more mobile phones, communicate using beamforming on millimeter wave frequency bands in the range of 30 GHz to 300 GHz and/or upper centimeter wave frequencies in the range of 6 GHz to 30 GHz, or more particularly, 24 GHz to 30 GHz.

Different users of the communication network 10 can share available network resources, such as available frequency spectrum, in a wide variety of ways.

In one example, frequency division multiple access (FDMA) is used to divide a frequency band into multiple frequency carriers. Additionally, one or more carriers are allocated to a particular user. Examples of FDMA include, but are not limited to, single carrier FDMA (SC-FDMA) and orthogonal FDMA (OFDMA). OFDMA is a multicarrier technology that subdivides the available bandwidth into multiple mutually orthogonal narrowband subcarriers, which can be separately assigned to different users.

Other examples of shared access include, but are not limited to, time division multiple access (TDMA) in which a user is allocated particular time slots for using a frequency resource, code division multiple access (CDMA) in which a frequency resource is shared amongst different users by assigning each user a unique code, space-divisional multiple access (SDMA) in which beamforming is used to provide shared access by spatial division, and non-orthogonal multiple access (NOMA) in which the power domain is used for multiple access. For example, NOMA can be used to serve multiple users at the same frequency, time, and/or code, but with different power levels.

Enhanced mobile broadband (eMBB) refers to technology for growing system capacity of LTE networks. For example, eMBB can refer to communications with a peak data rate of at least 10 Gbps and a minimum of 100 Mbps for each user. Ultra-reliable low latency communications (uRLLC) refers to technology for communication with very low latency, for instance, less than 2 milliseconds. uRLLC can be used for mission-critical communications such as for autonomous driving and/or remote surgery applications. Massive machine-type communications (mMTC) refers to low cost and low data rate communications associated with wireless connections to everyday objects, such as those associated with Internet of Things (IoT) applications.

The communication network 11 of FIG. 1 can be used to support a wide variety of advanced communication features, including, but not limited to, eMBB, uRLLC, and/or mMTC.

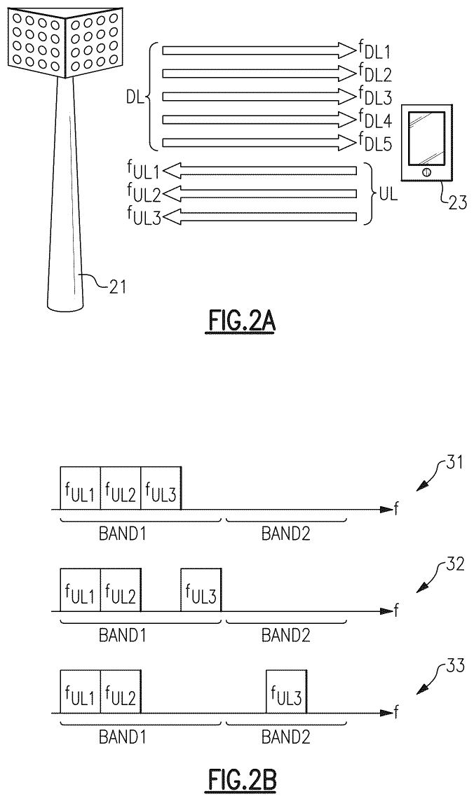

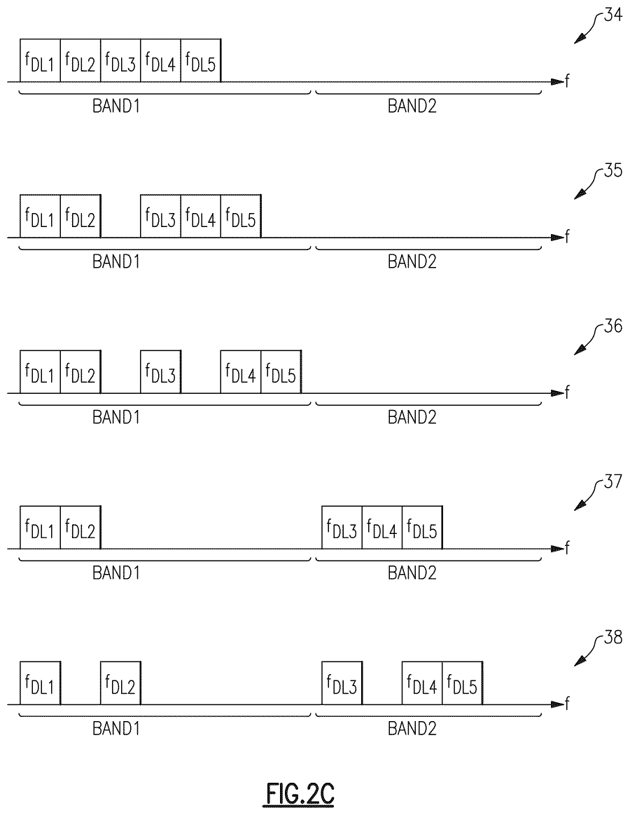

FIG. 2A is a schematic diagram of one example of a communication link using carrier aggregation. Carrier aggregation can be used to widen bandwidth of the communication link by supporting communications over multiple frequency carriers, thereby increasing user data rates and enhancing network capacity by utilizing fragmented spectrum allocations.

In the illustrated example, the communication link is provided between a base station 21 and a mobile device 23. As shown in FIG. 2A, the communications link includes a downlink channel used for RF communications from the base station 21 to the mobile device 23, and an uplink channel used for RF communications from the mobile device 23 to the base station 21.

Although FIG. 2A illustrates carrier aggregation in the context of FDD communications, carrier aggregation can also be used for TDD communications.

In certain implementations, a communication link can provide asymmetrical data rates for a downlink channel and an uplink channel. For example, a communication link can be used to support a relatively high downlink data rate to enable high speed streaming of multimedia content to a mobile device, while providing a relatively slower data rate for uploading data from the mobile device to the cloud.

In the illustrated example, the base station 21 and the mobile device 23 communicate via carrier aggregation, which can be used to selectively increase bandwidth of the communication link. Carrier aggregation includes contiguous aggregation, in which contiguous carriers within the same operating frequency band are aggregated. Carrier aggregation can also be non-contiguous, and can include carriers separated in frequency within a common band or in different bands.

In the example shown in FIG. 2A, the uplink channel includes three aggregated component carriers f_{UL1}, f_{UL2}, and f_{UL3}. Additionally, the downlink channel includes five aggregated component carriers f_{DL1}, f_{DL2}, f_{DL3}, f_{DL4}, and f_{DL5}. Although one example of component carrier aggregation is shown, more or fewer carriers can be aggregated for uplink and/or downlink. Moreover, a number of aggregated carriers can be varied over time to achieve desired uplink and downlink data rates.

For example, a number of aggregated carriers for uplink and/or downlink communications with respect to a particular mobile device can change over time. For example, the number of aggregated carriers can change as the device moves through the communication network and/or as network usage changes over time.

FIG. 2B illustrates various examples of uplink carrier aggregation for the communication link of FIG. 2A. FIG. 2B includes a first carrier aggregation scenario 31, a second carrier aggregation scenario 32, and a third carrier aggregation scenario 33, which schematically depict three types of carrier aggregation.

The carrier aggregation scenarios 31-33 illustrate different spectrum allocations for a first component carrier fun, a second component carrier f_{UL2}, and a third component carrier f_{UL3}. Although FIG. 2B is illustrated in the context of aggregating three component carriers, carrier aggregation can be used to aggregate more or fewer carriers. Moreover, although illustrated in the context of uplink, the aggregation scenarios are also applicable to downlink.

The first carrier aggregation scenario 31 illustrates intra-band contiguous carrier aggregation, in which component carriers that are adjacent in frequency and in a common frequency band are aggregated. For example, the first carrier aggregation scenario 31 depicts aggregation of component carriers f_{UL1}, f_{UL2}, and f_{UL3} that are contiguous and located within a first frequency band BAND1.

With continuing reference to FIG. 2B, the second carrier aggregation scenario 32 illustrates intra-band non-continuous carrier aggregation, in which two or more components carriers that are non-adjacent in frequency and within a common frequency band are aggregated. For example, the second carrier aggregation scenario 32 depicts aggregation of component carriers f_{UL1}, f_{UL2}, and f_{UL3} that are non-contiguous, but located within a first frequency band BAND1.

The third carrier aggregation scenario 33 illustrates inter-band non-contiguous carrier aggregation, in which component carriers that are non-adjacent in frequency and in multiple frequency bands are aggregated. For example, the third carrier aggregation scenario 33 depicts aggregation of component carriers f_{UL1} and f_{UL2} of a first frequency band BAND1 with component carrier f_{UL3} of a second frequency band BAND2.

FIG. 2C illustrates various examples of downlink carrier aggregation for the communication link of FIG. 2A. The examples depict various carrier aggregation scenarios 34-38 for different spectrum allocations of a first component carrier f_{DL1}, a second component carrier f_{DL2}, a third component carrier f_{DL3}, a fourth component carrier f_{DL4}, and a fifth component carrier f_{DL5}. Although FIG. 2C is illustrated in the context of aggregating five component carriers, carrier aggregation can be used to aggregate more or fewer carriers. Moreover, although illustrated in the context of downlink, the aggregation scenarios are also applicable to uplink.

The first carrier aggregation scenario 34 depicts aggregation of component carriers that are contiguous and located within the same frequency band. Additionally, the second carrier aggregation scenario 35 and the third carrier aggregation scenario 36 illustrates two examples of aggregation that are non-contiguous, but located within the same frequency band. Furthermore, the fourth carrier aggregation scenario 37 and the fifth carrier aggregation scenario 38 illustrates two examples of aggregation in which component carriers that are non-adjacent in frequency and in multiple frequency bands are aggregated. As a number of aggregated component carriers increases, a complexity of possible carrier aggregation scenarios also increases.

With reference to FIGS. 2A-2C, the individual component carriers used in carrier aggregation can be of a variety of frequencies, including, for example, frequency carriers in the same band or in multiple bands. Additionally, carrier aggregation is applicable to implementations in which the individual component carriers are of about the same bandwidth as well as to implementations in which the individual component carriers have different bandwidths.

Certain communication networks allocate a particular user device with a primary component carrier (PCC) or anchor carrier for uplink and a PCC for downlink. Additionally, when the mobile device communicates using a single frequency carrier for uplink or downlink, the user device communicates using the PCC. To enhance bandwidth for uplink communications, the uplink PCC can be aggregated with one or more uplink secondary component carriers (SCCs). Additionally, to enhance bandwidth for downlink communications, the downlink PCC can be aggregated with one or more downlink SCCs.

In certain implementations, a communication network provides a network cell for each component carrier. Additionally, a primary cell can operate using a PCC, while a secondary cell can operate using a SCC. The primary and secondary cells may have different coverage areas, for instance, due to differences in frequencies of carriers and/or network environment.

License assisted access (LAA) refers to downlink carrier aggregation in which a licensed frequency carrier associated with a mobile operator is aggregated with a frequency carrier in unlicensed spectrum, such as WiFi. LAA employs a downlink PCC in the licensed spectrum that carries control and signaling information associated with the communication link, while unlicensed spectrum is aggregated for wider downlink bandwidth when available. LAA can operate with dynamic adjustment of secondary carriers to avoid WiFi users and/or to coexist with WiFi users. Enhanced license assisted access (eLAA) refers to an evolution of LAA that aggregates licensed and unlicensed spectrum for both downlink and uplink.

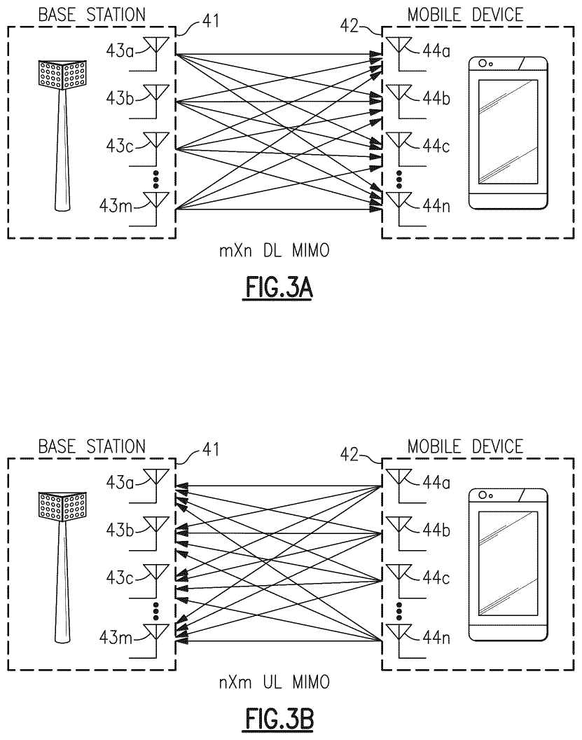

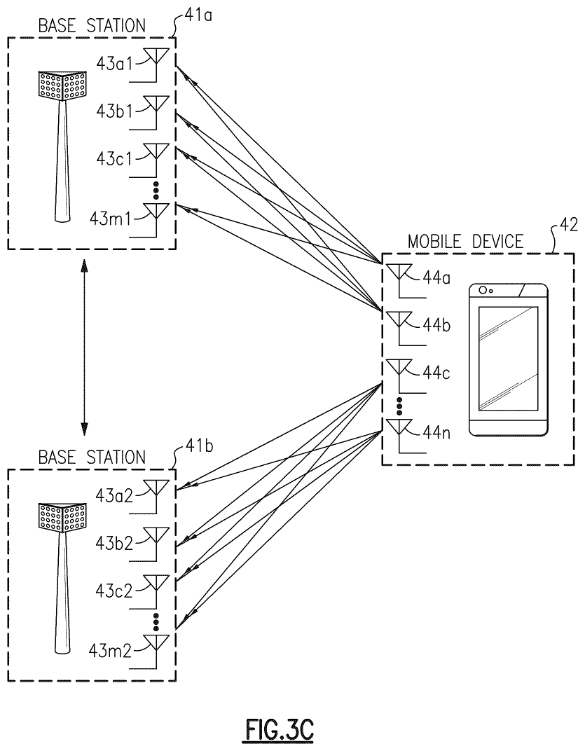

FIG. 3A is a schematic diagram of one example of a downlink channel using multi-input and multi-output (MIMO) communications. FIG. 3B is schematic diagram of one example of an uplink channel using MIMO communications.

MIMO communications use multiple antennas for simultaneously communicating multiple data streams over common frequency spectrum. In certain implementations, the data streams operate with different reference signals to enhance data reception at the receiver. MIMO communications benefit from higher SNR, improved coding, and/or reduced signal interference due to spatial multiplexing differences of the radio environment.

MIMO order refers to a number of separate data streams sent or received. For instance, MIMO order for downlink communications can be described by a number of transmit antennas of a base station and a number of receive antennas for UE, such as a mobile device. For example, two-by-two (2×2) DL MIMO refers to MIMO downlink communications using two base station antennas and two UE antennas. Additionally, four-by-four (4×4) DL MIMO refers to MIMO downlink communications using four base station antennas and four UE antennas.

In the example shown in FIG. 3A, downlink MIMO communications are provided by transmitting using M antennas 43a, 43b, 43c, . . . 43m of the base station 41 and receiving using N antennas 44a, 44b, 44c, . . . 44n of the mobile device 42. Accordingly, FIG. 3A illustrates an example of m×n DL MIMO.

Likewise, MIMO order for uplink communications can be described by a number of transmit antennas of UE, such as a mobile device, and a number of receive antennas of a base station. For example, 2×2 UL MIMO refers to MIMO uplink communications using two UE antennas and two base station antennas. Additionally, 4×4 UL MIMO refers to MIMO uplink communications using four UE antennas and four base station antennas.

In the example shown in FIG. 3B, uplink MIMO communications are provided by transmitting using N antennas 44a, 44b, 44c, . . . 44n of the mobile device 42 and receiving using M antennas 43a, 43b, 43c, . . . 43m of the base station 41. Accordingly, FIG. 3B illustrates an example of n×m UL MIMO.

By increasing the level or order of MIMO, bandwidth of an uplink channel and/or a downlink channel can be increased.

MIMO communications are applicable to communication links of a variety of types, such as FDD communication links and TDD communication links.

FIG. 3C is schematic diagram of another example of an uplink channel using MIMO communications. In the example shown in FIG. 3C, uplink MIMO communications are provided by transmitting using N antennas 44a, 44b, 44c, . . . 44n of the mobile device 42. Additional a first portion of the uplink transmissions are received using M antennas 43a1, 43b1, 43c1, . . . 43m1 of a first base station 41a, while a second portion of the uplink transmissions are received using M antennas 43a2, 43b2, 43c2, . . . 43m2 of a second base station 41b. Additionally, the first base station 41a and the second base station 41b communication with one another over wired, optical, and/or wireless links.

The MIMO scenario of FIG. 3C illustrates an example in which multiple base stations cooperate to facilitate MIMO communications.

Uplink carrier aggregation (UL CA) combines two or more wireless (e.g., 5G) signals (component carriers), transmitted (uplinked) from a single user device to a wireless base station, dramatically increasing the speed with which a user can upload content and files. Similarly, downlink carrier aggregation (DL CA) combines two or more wireless (e.g., LTE) signals (component carriers), received (downlinked) by a single user device from a wireless base station, dramatically increasing the speed with which a user can download content and files. In the user device, front-end modules and architectures can be provided that support UL CA and/or DL CA.

Disclosed herein are, among others, examples related to front-end module designs that support CA, including considerations for: front-end module integration; power, gain, noise, and/or linearity budget for CA front-end modules; envelope tracking for CA; and passive integration including diplexers, duplexers, and/or filters. In particular, the front-end modules disclosed herein provide advantages in CA based at least in part on the combination of features provided by the modules. For example, the disclosed front-end modules include power amplifiers (PAs) for signals to be transmitted, low noise amplifiers (LNAs) for received signals, antenna switch modules, multiplexers (e.g., diplexers, triplexers, etc.), duplexers, and envelope tracking.

Particular advantages can be realized using the disclosed front-end modules. For example, some embodiments of the disclosed front-end modules include envelope tracking as part of the module. In some embodiments, envelope tracking may be included in a PA module to increase efficiency and/or to improve performance of the amplification path for signals to be transmitted. As another example, some embodiments of the disclosed front-end modules include band-specific filters and/or duplexers to process frequency division duplex (FDD) cellular frequency bands and time division duplex (TDD) frequency cellular bands. In certain implementations, a notch filter can be included on the front-end module to extract wireless local area network (WLAN) signals from the cellular frequency bands (e.g., from cellular band B40). As another example, some embodiments of the disclosed front-end modules include a bypass switch to provide a bypass path for transmission signals to bypass the PA module. As another example, some embodiments of the disclosed front-end modules include LNAs on the module to amplify received signals in a plurality of TDD cellular frequency bands. As another example, some embodiments of the disclosed front-end modules direct received signals in one or more FDD cellular frequency bands to a separate module for amplification to reduce degradation of signal quality on the front-end module.

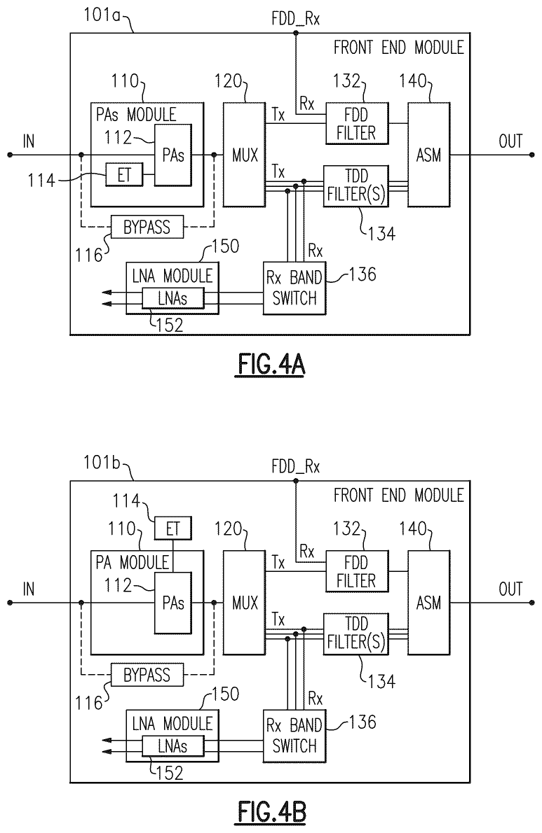

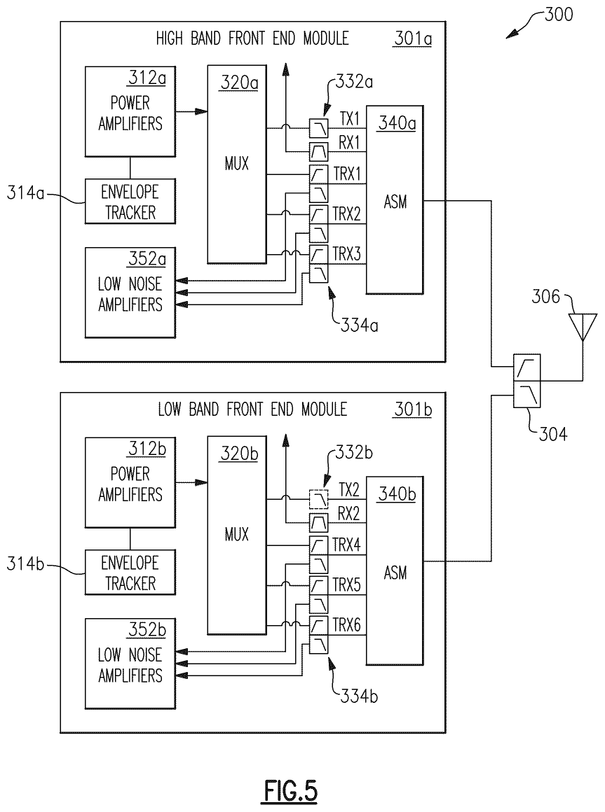

FIGS. 4A and 4B illustrate example front-end modules 101a, 101b that support carrier aggregation. The front-end module 101a of FIG. 4A includes a power amplifier module 110 including one or more power amplifiers (PAs) 112 configured to amplify signals received at a transceiver port (IN). The front-end module 101a includes an envelope tracker 114 configured to modify a supply voltage to the power amplifiers 112 to increase efficiency of the one or more power amplifiers 112. In the front-end module 101a, the envelope tracker 114 is implemented as part of the power amplifier module 110. In the front-end module 101b of FIG. 4B, the envelope tracker 114 is implemented outside of the power amplifier module 110.

The front-end module 101a includes a multiplexer 120 coupled to the power amplifier module 110. The multiplexer 120 is configured to direct signals along a plurality of paths. The multiplexer 120 can be implemented as a switch and can include one or more poles and/or throws. The multiplexer 120 can be configured to receive signals from the power amplifier module 110 and to direct those received signals along a plurality of paths to targeted filters and/or duplexers for further processing.

The front-end module 101a includes an antenna switch module (ASM) 140 coupled to an antenna port (OUT) and is configured to couple to at least a subset of the plurality of paths of the multiplexer 120. The ASM can be a single pole multiple throw (SPMT) switch with individual throws coupled to individual filters and/or individual duplexers. The ASM 140 is configured to direct transmission signals to the antenna port for transmission over an antenna. Similarly, the ASM 140 is configured to direct received signals from the antenna port to targeted duplexers and/or filters.

The front-end module 101a includes one or more frequency division duplex (FDD) filters 132 to filter FDD signals in one or more FDD cellular frequency bands. The FDD filter 132 is coupled to the multiplexer 120 to receive FDD signals for transmission. The FDD filter 132 can include a first duplexer configured to process signals that utilize a frequency division duplex scheme. The FDD filter 132 is coupled to the ASM 140 to direct received FDD signals to an FDD output port (FDD_Rx). These signals can be directed to a low noise amplifier on another module, different from the front-end module 101a.

The front-end module 101a includes one or more time division duplex (TDD) filters 134 to filter TDD signals in one or more TDD cellular frequency bands. The TDD filters 134 are coupled to the ASM 140 to direct received TDD signals to low noise amplifiers for amplification. The TDD filters 134 are also coupled to the multiplexer 120 to receive TDD signals for transmission. The TDD filters 134 can include a second duplexer configured to process signals that utilize a time division duplex scheme.

Accordingly, the ASM 140 is configured to direct signals between an antenna port (OUT) and the FDD filter 132 and/or the TDD filter(s) 134. Although three lines are shown from the ASM 140 to the TDD filter 134 and a single line is shown from the ASM 140 to the FDD filter 132, it is to be understood that one or more signals or cellular frequency bands may be directed between the ASM 140 and the FDD filter 132 as well as one or more signals or cellular frequency bands may be directed between the ASM 140 and the TDD filter(s) 134. It is also to be understood that the front-end module 101a includes impedance matching components, filters, phase shifting components, and the like to reduce signal degradation through the module.

The front-end module 101a also includes a low noise amplifier module 150 that includes one or more low noise amplifiers 152 configured to amplify signals received at the antenna port (OUT). The low noise amplifier module 152 is coupled to the TDD filter(s) 134 to amplify signals that utilize the time division duplex scheme. The front-end module 101a also includes an Rx band switch 136 coupled to the TDD filter(s) 134 and to the LNA module 150. The Rx band switch 136 is configured to receive a plurality of receive (Rx) TDD signals from the TDD filter(s) 134 and to selectively direct the received signals to targeted LNAs 152. The Rx band switch 136 can include single pole single throw switches to selectively couple an Rx path from a particular TDD filter 134 to a particular LNA 152. Similarly, the Rx band switch 136 can include single pole multiple throw switches to alternately switch between coupling a first Rx path from a first TDD filter 134 to a targeted LNA and a second Rx path from a second TDD filter 134 to the targeted LNA. In this way, the Rx band switch 136 enables a single LNA 152 to amplify signals from a plurality of different cellular frequency bands.

In some embodiments, the front-end module 101a includes a bypass switch 116 that provides a bypass path from the transceiver port (IN) to the multiplexer 120 to bypass the one or more power amplifiers 112 of the power amplifier module 110. It is to be understood that although not shown, the front-end module 101a includes a controller configured to control switching and routing of the bypass switch 116, the multiplexer 120, the ASM 140, and/or the Rx band switch 136.

FIG. 4B illustrates a front-end module 101b that is similar to the front-end module 101a except that the envelope tracker 114 is implemented outside of the power module 110.

Each of the front-end modules 101a, 101b can be implemented as a module that includes a packaging substrate with a number of components mounted on such a packaging substrate. For example, a controller (which may include a front-end power management integrated circuit [FE-PMIC]), the PA module 110, the LNA module 150, the multiplexer 120, the FDD filters 132, the TDD filters 134, the Rx band switches 136, and the antenna switch module 140 can be mounted and/or implemented on and/or within the packaging substrate. Other components, such as a number of SMT devices, can also be mounted on the packaging substrate.

FIG. 5 illustrates a wireless communication configuration 300 for uplink and/or downlink carrier aggregation using front-end modules 301a, 301b for particular ranges of cellular frequency bands. The wireless communication configuration 300 includes an antenna 306 configured to receive wireless signals within a plurality of cellular frequency bands.

The wireless communication configuration 300 includes a multiplexer 304 coupled to the antenna, the multiplexer 304 including a first filter configured to pass signals within a first frequency range and a second filter configured to pass signals within a second frequency range different from the first frequency range. The multiplexer 304 is illustrated as a diplexer, but it is to be understood that the multiplexer 304 can be a triplexer or any other suitable combination of low-pass filters, high-pass filters, and/or bandpass filters. In the illustrated embodiment, the high-pass filter couples high-band signals between the antenna 306 and a high band (HB) front end module 301a and the low-pass filter couples low-band signals between the antenna 306 and a low-band (LB) front end module 301b. The multiplexer 304 can include a low-pass filter that passes low-band cellular frequencies to the LB front-end module 301b and a high-pass or band-pass filter that passes mid-band and high-band cellular signals as well as WLAN signals to the HB front-end module 301a. The multiplexer 304 can include a high-pass filter that passes ultrahigh-band (UHB) cellular signals and/or higher frequency WLAN signals to another multiplexer or module (not shown).

The multiplexer 304 can be configured to pass first signals having a frequency above a first threshold along a first path and to pass second signals having a frequency below a second threshold along a second path. In some embodiments, the first threshold is greater than or equal to the second threshold. The first signals can include cellular signals (e.g., mid- and/or high-band cellular frequencies) mixed with WLAN signals and the second signals can include cellular signals (e.g., low-band cellular frequencies). In some embodiments, the first signals include cellular signals (e.g., mid- and/or high-band cellular frequencies) with or without WLAN signals and the second signals include cellular signals (e.g., low-band cellular frequencies). As an example, the multiplexer 304 can have a variety of different configurations such as a diplexer that provides the functionality of a high pass filter and a low pass filter. In certain implementations, the multiplexer 304 comprises a multi-layer ceramic device, such as a low-temperature co-fired ceramic.

Each of the HB front-end module 301a and the LB front-end module 301b are similar to the front-end modules 101a and 101b described herein with respect to FIGS. 1A and 1B, respectively. Accordingly, a full description of similar components will not be provided again. In one or both of the front end modules 301a, 301b, the antenna switch module 340a, 340b includes a single pole, multiple throw (SPMT) switch wherein the pole is coupled to an antenna port and a first throw is coupled to a first filter (e.g., TX1 in front-end module 301a or TX2 in front-end module 301b) of a first duplexer 332a or 332b, a second throw is coupled to a second filter (e.g., RX1 in front-end module 301a or RX2 in front-end module 301b) of the first duplexer 332a or 332b, and a third throw is coupled to the second duplexer (e.g., TRX1 in front-end module 301a or TRX4 in front-end module 301b) of the TDD duplexers 334a or 334b.

Although not shown, the wireless communication configuration 300 can include an off-module low noise amplifier apart from the HB front-end module 301a and from the LB front-end module 301b. The off-module low noise amplifier is configured to amplify signals received from the HB front-end module (e.g., RX1) and/or to amplify signals received from the LB front-end module (e.g., RX2).

The wireless communication configuration 300 can be configured to perform downlink carrier aggregation where the HB front-end module 301a is configured to process high-band cellular signals for transmission and to process high-band cellular signals directed to the HB front-end module 301a from the multiplexer 304. The wireless communication configuration 300 is further configured to perform downlink carrier aggregation where the LB front-end module 301b is configured to process low-band cellular signals directed to the LB front-end module 301b from the multiplexer 304.

The wireless communication configuration 300 can be configured to perform uplink carrier aggregation where the HB front-end module 301a is configured to process high-band cellular signals for transmission and to process high-band cellular signals directed to the HB front-end module 301a from the multiplexer 304. The wireless communication configuration 300 is further configured to perform uplink carrier aggregation where the LB front-end module 301b is configured to process low-band cellular signals for transmission and to process low-band cellular signals directed to the LB front-end module 301b from the multiplexer 304.

Although not shown, it is to be understood that the wireless communication configuration 300 can further include one or more third front-end module (e.g., an ultrahigh-band front-end module and/or a mid-band front-end module) coupled to a bandpass filter of the multiplexer 304. It is also to be understood that the HB front-end module 301a can be implemented on a first packaging substrate and the LB front-end module 301b can be implemented on a second, separate packaging substrate.

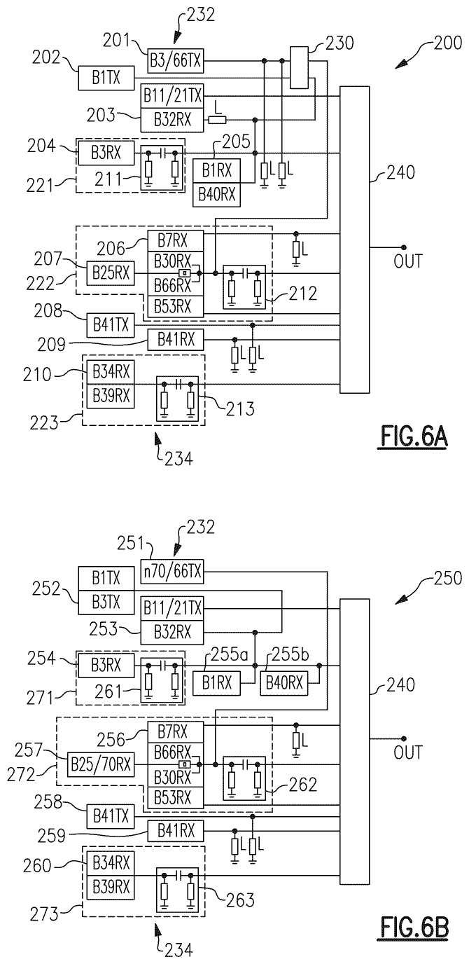

FIG. 6A is a schematic diagram of details of a front-end module 200 supporting carrier aggregation according to one embodiment. The front-end module (FEM) 200 shown in FIG. 6A depicts an acoustic wave filter module with FDD filters 232 and TDD filters 234, an antenna switch module (ASM) 240, and the corresponding transmission lines connecting the acoustic wave filter module to the ASM 240. The ASM 240 is coupled to an output port OUT that may be coupled to one or more antennas for receiving and transmitting radio-frequency (RF) signals, for example via a multiplexer such as the multiplexer 304 in FIG. 5. The FEM 200 may in particular be a possible implementation of the front-end modules 101a, 101b, 301a, or 301b, as illustrated in conjunction with FIGS. 4A, 4B, and 5, respectively.

The acoustic wave filter module includes a number of acoustic wave filters 201 to 210 which may be used to filter a number of RF bands, either in transmission or in reception direction. For example, the filter 201 may be an acoustic wave filter used for filtering RF signals in the B3 and the B66 band sent from a transceiver to a power amplifier module for amplification, filtered by the filter 201, and sent onward through the ASM 240 to one or more antennas for transmission. Some of the filters 201 to 210 may be surface acoustic wave (SAW) resonator filters, some others of the filters 201 to 210 may be bulk acoustic wave (BAW) resonator filters. Some of the filters 201 to 210 may implemented as duplexers, diplexers, quadplexers, hexaplexers, octaplexers, or other types of multiplexers. In some forms of implementation, each of the filters 201 to 210 may be implemented on a separate die or chip. In some other forms of implementation, some of the filters 201 to 210 may be co-located together on a common die or chip. The exemplary configuration of filters 201 to 210 in FIG. 6A may, in some implementations, more or less filters than explicitly illustrated.

In some cases, the FEM 200 may include one or more multiplexers like the multiplexer 230 connecting two or more of the transmission lines between one or more of the filters 201 to 210 to an input of the ASM 240. For example, the filters 201 and 202 in in FIG. 6A may, in some implementations, be connected to a multiplexer 230 to route the amplified and filtered RF signals in certain transmission bands to different transmission lines.

The filters 201 to 210 may in some implementations be implemented on multi-chip modules (MCM) together with power amplifier modules, low noise amplifier (LNA) modules, the ASM 240, and possibly other modules like multiplexer modules and similar modules on the same substrate.

FIG. 6B is a schematic diagram of details of a front-end module 250 supporting carrier aggregation according to another embodiment. The front-end module (FEM) 250 shown in FIG. 6B depicts an acoustic wave filter module with FDD filters 232 and TDD filters 234, an antenna switch module (ASM) 240, and the corresponding transmission lines connecting the acoustic wave filter module to the ASM 240. The ASM 240 is coupled to an output port OUT that may be coupled to one or more antennas for receiving and transmitting radio-frequency (RF) signals, for example via a multiplexer such as the multiplexer 304 in FIG. 5. The FEM 250 may in particular be a possible implementation of the front-end modules 101a, 101b, 301a, or 301b, as illustrated in conjunction with FIGS. 4A, 4B, and 5, respectively.

The acoustic wave filter module includes a number of acoustic wave filters 251 to 260 which may be used to filter a number of RF bands, either in transmission or in reception direction. For example, the filter 251 may be an acoustic wave filter used for filtering RF signals in the n70 and the B66 band sent from a transceiver to a power amplifier module for amplification, filtered by the filter 251, and sent onward through the ASM 240 to one or more antennas for transmission. Some of the filters 251 to 260 may be surface acoustic wave (SAW) resonator filters, some others of the filters 251 to 260 may be bulk acoustic wave (BAW) resonator filters. Some of the filters 251 to 260 may implemented as duplexers, diplexers, quadplexers, hexaplexers, octaplexers, or other types of multiplexers. In some forms of implementation, each of the filters 251 to 260 may be implemented on a separate die or chip. In some other forms of implementation, some of the filters 251 to 260 may be co-located together on a common die or chip. The exemplary configuration of filters 251 to 260 in FIG. 6A may, in some implementations, more or less filters than explicitly illustrated.

In some cases, the FEM 250 may include one or more multiplexers connecting two or more of the transmission lines between one or more of the filters 251 to 260 to an input of the ASM 240.

The filters 251 to 260 may in some implementations be implemented on multi-chip modules (MCM) together with power amplifier modules, low noise amplifier (LNA) modules, the ASM 240, and possibly other modules like multiplexer modules and similar modules on the same substrate.

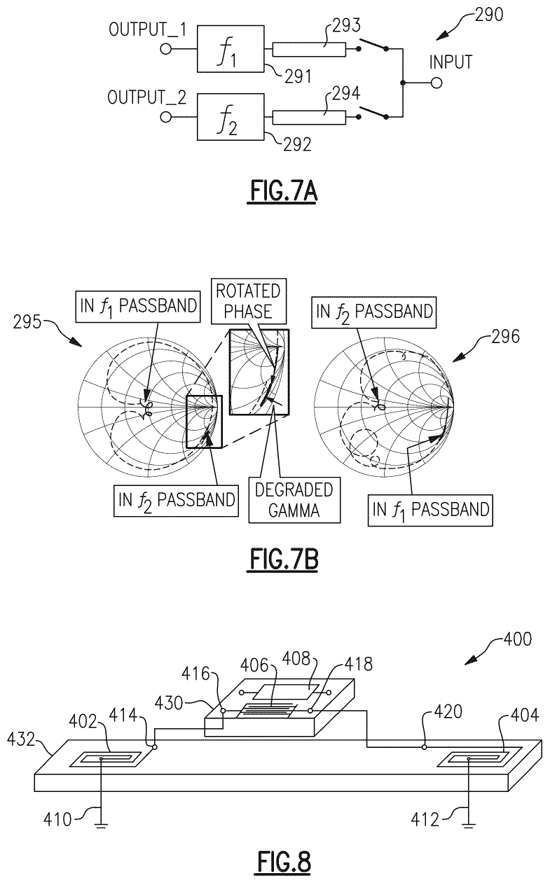

In both of the FEMs 200 and 250, the physical implementation of the various acoustic wave filters on different or separate dies and the interconnections of different filters require various lengths of the transmission lines. FIG. 7A schematically illustrates a simplified example of a filter network 290 having two acoustic wave filters 291 and 292 connected in parallel between respective output ports Output_1 and Output_2 and a common input port Input. The transmission line 293 between the first acoustic wave filter 291 and the input port and the transmission line 294 between the second acoustic wave filter 292 and the input port have different lengths giving rise to a phase shift between RF signals travelling on the different transmission lines 293 and 294. This phase shift will degrade the reflection coefficient at the input of each of the acoustic wave filters in the pass band frequency of the respective other acoustic wave filters.

For example—and as illustrated in the Smith charts 295 and 296 of FIG. 7B—the first acoustic wave filter 291 has a passband at a first frequency f₁ and the second acoustic wave filter 292 has a passband at a second frequency f₂. A mismatch in time delays and resistances between the different transmission lines 293 and 294 may result in the S11 parameter in the f₂ passband of the first acoustic wave filter 291 being rotated in phase yielding a degradation in the reflection coefficient F of the first acoustic wave filter 291, while the S11 parameter in the f₁ passband of the second acoustic wave filter 292 is equally rotated in phase yielding a degradation in the reflection coefficient F of the second acoustic wave filter 292.

In order to counter such degradation, a π-type high pass filter including a capacitor and two shunt inductors shunting a node before the capacitor and a node after the capacitor, respectively, against ground may be electrically connected between the input port and the acoustic wave filter. For example, in the FEM 200 of FIG. 6A, a first π-type high pass filter 211 is electrically connected in the transmission line between a first acoustic wave filter 204 and the antenna switch module 240. A second π-type high pass filter 212 is electrically connected in the transmission line between a second acoustic wave filter 206 and the antenna switch module 240. A third π-type high pass filter 213 is electrically connected in the transmission line between a second acoustic wave filter 210 and the antenna switch module 240. While two inductors and a single capacitor are included in the embodiment of FIG. 6A, in some embodiments additional capacitor(s) or inductor(s) can be included in the FEM 200. As an example, more than one inductor can be included in series in either or both inductive branches of one or more of the high pass filters 211, 212, 213.

Similarly, in the FEM 250 of FIG. 6B, a first π-type high pass filter 261 is electrically connected in the transmission line between a first acoustic wave filter 254 and the antenna switch module 240. A second π-type high pass filter 262 is electrically connected in the transmission line between a second acoustic wave filter 256 and the antenna switch module 240. A third π-type high pass filter 263 is electrically connected in the transmission line between a second acoustic wave filter 260 and the antenna switch module 240. While two inductors and a single capacitor are included in the embodiment of FIG. 6B, in some embodiments additional capacitor(s) or inductor(s) can be included in the FEM 250. As an example, more than one inductor can be included in series in either or both inductive branches of one or more of the high pass filters 261, 262, 263.

Conventionally, such π-type high pass filters would be implemented as separate dies on a multi-chip module (MCM). However, in order to reduce the module size of such an MCM, the π-type high pass filters may be co-located on the same substrate as the associated acoustic wave filter. FIG. 8 illustrates an acoustic wave filter module 400 with an integrated phase shift circuit according to an embodiment. The acoustic wave filter module 400 includes a piezoelectric substrate 430, such as for example a lithium tantalite or a lithium niobate substrate. A surface acoustic wave (SAW) filter 408 is mounted on the surface of the substrate 430. A capacitor 406 is mounted on the substrate 430 as well, either on the same surface as the SAW filter 408 or on a surface opposite to the SAW filter 408. The piezoelectric substrate 430 is mounted on a metal plate 432, for example a copper plate. A first inductor 402 is mounted on a surface of the metal plate 432. A second inductor 404 is mounted on the surface of the metal plate 432. A first port 410 of the first inductor 402 is electrically connected to ground, while a second port 414 of the first inductor 402 is electrically connected to a first terminal 416 of the capacitor 406. A first port 412 of the second inductor 404 is electrically connected to ground, while a second port 420 of the second inductor 404 is electrically connected to a second terminal 418 of the capacitor 406. The first inductor 402, the second inductor 404, and the capacitor 406 thereby implemented an LCL network acting as a π-type high pass filter. The π-type high pass filter is electrically connected in series to the SAW filter 408. In some implementations, the first inductor 402 and the second inductor 404 have the same inductivity value. While two inductors and a single capacitor are included in the embodiment of FIG. 8, in some embodiments additional capacitor(s) or inductor(s) can be included in the module 400. As an example, more than one inductor can be included in series in either or both inductive branches.

While there is only a single SAW filter 408 depicted in FIG. 8, any number of SAW filters may be deposited on the piezoelectric substrate 430 in other embodiments. The co-location of the LCL network including the first inductor 402, the second inductor 404, and the capacitor 406 together with one or more SAW filters on the piezoelectric substrate 430 allows for reducing the number of separate dies needed for multi-chip modules (MCMs) forming a front-end module, such as the front-end module 200 of FIG. 6A or the front-end module 250 of FIG. 6B. The LCL network acts as a π-type high pass filter improving the reflection coefficient F and minimizing the phase rotation of the acoustic wave filter module 400. Transmission lines may be shortened to the greatest extent, and transmission line effects in other bands of a multiplexer may be removed. When co-locating capacitors of π-type high pass filters with SAW filters on the same piezoelectric substrate, the freedom in filter design may be expanded.

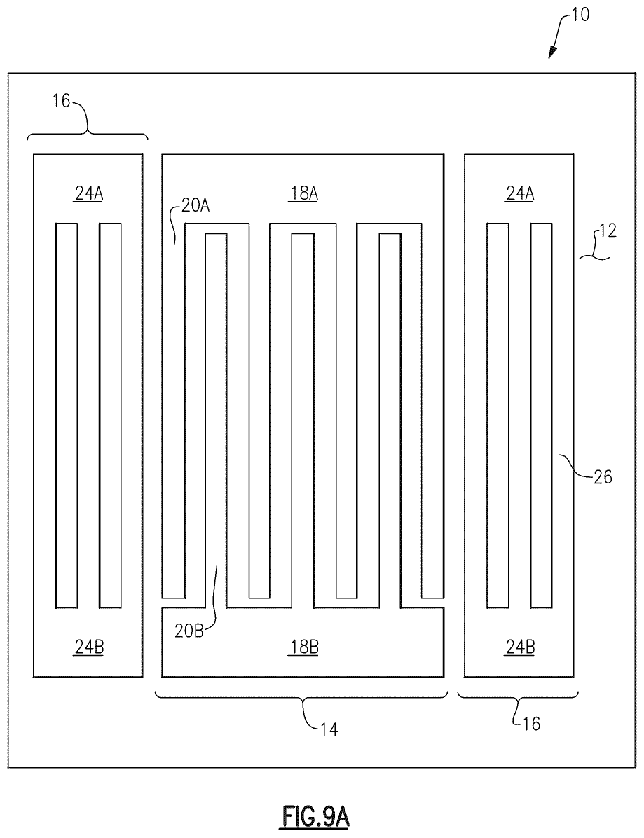

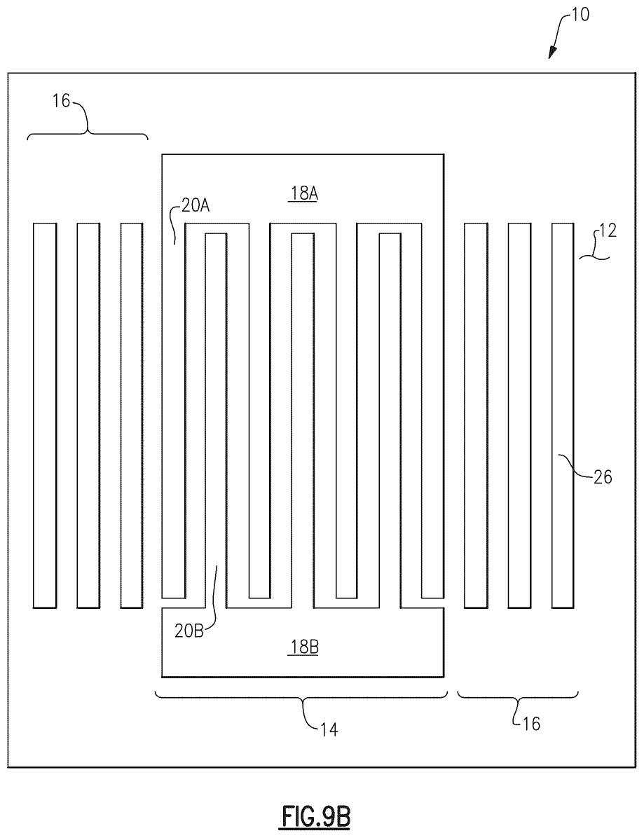

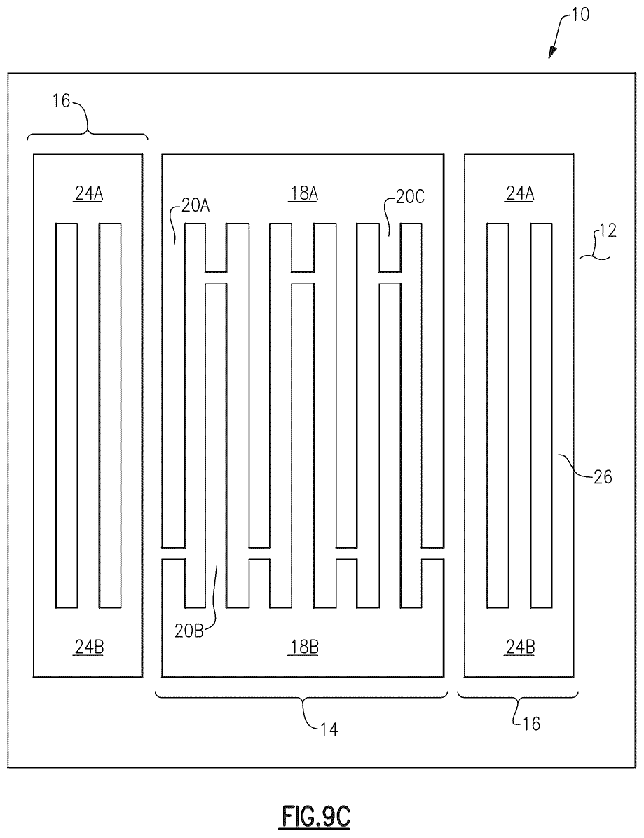

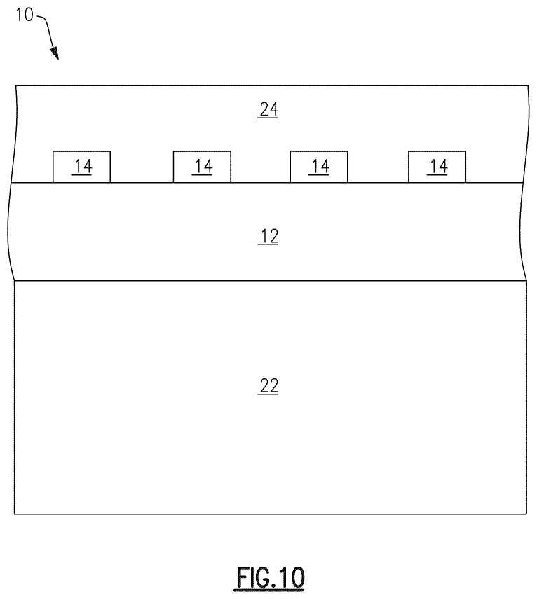

FIG. 9A is a plan view of a surface acoustic wave (SAW) resonator 10 such as might be used in a SAW filter, duplexer, diplexer, balun, etc., specifically in the SAW filter 408 on the piezoelectric substrate 430 of FIG. 8.

Acoustic wave resonator 10 is formed on a piezoelectric substrate, for example, a lithium tantalate (LiTaO₃) or lithium niobate (LiNbO₃) substrate 12 and includes Interdigital Transducer (IDT) electrodes 14 and reflector electrodes 16. In use, the IDT electrodes 14 excite a main acoustic wave having a wavelength λ along a surface of the piezoelectric substrate 12. The reflector electrodes 16 sandwich the IDT electrodes 14 and reflect the main acoustic wave back and forth through the IDT electrodes 14. The main acoustic wave of the device travels perpendicular to the lengthwise direction of the IDT electrodes.

The IDT electrodes 14 include a first bus bar electrode 18A and a second bus bar electrode 18B facing first bus bar electrode 18A. The bus bar electrodes 18A, 18B may be referred to herein together as busbar electrode 18. The IDT electrodes 14 further include first electrode fingers 20A extending from the first bus bar electrode 18A toward the second bus bar electrode 18B, and second electrode fingers 20B extending from the second bus bar electrode 18B toward the first bus bar electrode 18A.

The reflector electrodes 16 (also referred to as reflector gratings) each include a first reflector bus bar electrode 24A and a second reflector bus bar electrode 24B (collectively referred to herein as reflector bus bar electrode 24) and reflector fingers 26 extending between and electrically coupling the first bus bar electrode 24A and the second bus bar electrode 24B.

In other embodiments disclosed herein, as illustrated in FIG. 9B, the reflector bus bar electrodes 24A, 24B may be omitted and the reflector fingers 26 may be electrically unconnected. Further, as illustrated in FIG. 9C, acoustic wave resonators as disclosed herein may include dummy electrode fingers 20C that are aligned with respective electrode fingers 20A, 20B. Each dummy electrode finger 20C extends from the opposite bus bar electrode 18A, 18B than the respective electrode finger 20A, 20B with which it is aligned.

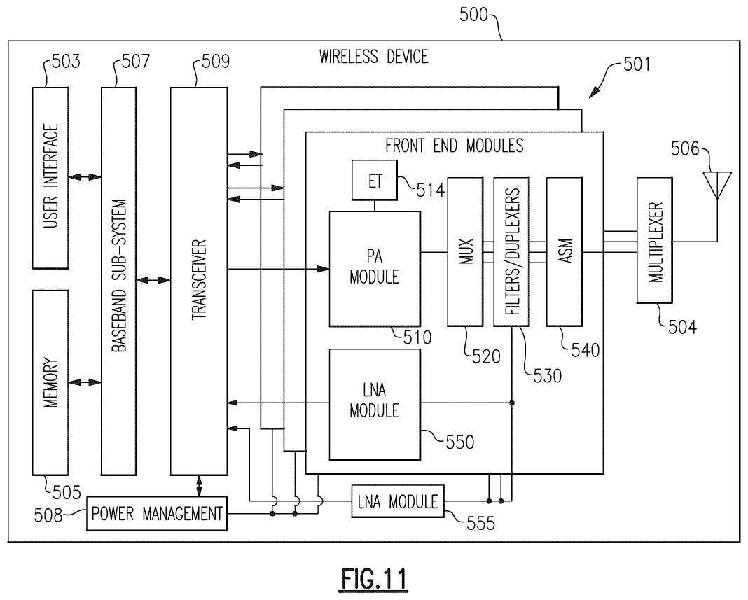

FIG. 10 is a partial cross-sectional view of a portion of the acoustic wave resonator 10 of any of FIGS. 9A to 9C illustrating a few of the IDT electrodes 14 disposed on the substrate 12. In some embodiments, an acoustic wave resonator may include a multilayer piezoelectric substrate including the piezoelectric substrate 12 and a carrier substrate 22 on which the piezoelectric substrate is disposed. The carrier substrate 22 may be formed of, for example, silicon or a dielectric material, for example, silicon dioxide, aluminum oxide, or sapphire. The carrier substrate 22 is typically thicker than the piezoelectric substrate 12 and provides the acoustic wave resonator with increased mechanical strength.

The IDT electrodes 14 are formed of a metal or metal alloy, for example, aluminum. In some embodiments the IDT electrodes 14 may include multiple layers of different metals, for example, molybdenum and aluminum. A dielectric material 24, for example, silicon dioxide (SiO2) may be disposed on top of the IDT electrodes 14 and substrate 12. The dielectric material may advantageously decrease the effect of changes in temperature upon operating characteristics of the acoustic wave resonator 10 and may protect the IDT electrodes 14 and surface of the substrate 12. For example, SiO2 has a negative coefficient of thermal expansion while materials typically used for the piezoelectric substrate 12 in a SAW device have a positive coefficient of thermal expansion. The layer of SiO2 24 may thus oppose changes in dimensions of piezoelectric substrate 12 with changes in temperature that might otherwise occur in the absence of the layer of SiO2 24. SAW devices including a layer of SiO2 as illustrated in FIG. 10 may be referred to as temperature-compensated SAW devices, often abbreviated as TC-SAW devices.

In some implementations, an architecture, a device and/or a circuit having one or more features described herein can be included in an RF device such as a wireless communication device. Such an architecture, a device and/or a circuit can be implemented directly in the wireless communication device, in one or more modular forms as described herein, or in some combination thereof. In some embodiments, such a wireless communication device can include, for example, a cellular phone, a smart-phone, a hand-held wireless device with or without phone functionality, a wireless tablet, a wireless router, a wireless access point, a wireless base station, etc.

FIG. 11 illustrates an example wireless communication device 500 having one or more advantageous features described herein. In some embodiments, such advantageous features can be implemented in one or more front-end (FE) modules generally indicated as 501. As described herein, such front-end modules 501 can include an antenna switch module (ASM) 540, filters and duplexers 530, a multiplexer 520, a power amplifier (PA) module 510, envelope tracking (ET) 514, low noise amplifier (LNA) module 550. In some embodiments, the envelope tracking 514 can be implemented as part of the PA module 510.

The PA module 510 includes a plurality of PAs that receive their respective RF signals from a transceiver 509 that can be configured and operated to generate RF signals to be amplified and transmitted, and to process received signals. The transceiver 509 interacts with a baseband sub-system 507 that is configured to provide conversion between data and/or voice signals suitable for a user and RF signals suitable for the transceiver 509. The transceiver 509 is connected to a power management component 508 (e.g., a power management integrated circuit or PMIC) that is configured to manage power for the operation of the wireless device 500. Such power management 508 can control operations of the baseband sub-system 507 and the front-end modules 501.

The baseband sub-system 507 is connected to a user interface 503 to facilitate various input and output of voice and/or data provided to and received from the user. The baseband sub-system 507 can also be connected to a memory 505 that is configured to store data and/or instructions to facilitate the operation of the wireless device, and/or to provide storage of information for the user.

In the example wireless communication device 500, the front-end modules 510 are coupled to an antenna 506 through a multiplexer 504. As described herein, the multiplexer 504 is configured to direct signals within particular cellular frequency bands to targeted front-end modules that are configured to handle signals within the corresponding frequency bands. For example, the wireless communication device 500 can include a low-band front-end module configured to handle low band cellular signals, a mid-band front-end module configured to handle mid-band cellular signals, and a high-band front-end module configured to handle high-band cellular signals. In some embodiments, the wireless communication device 500 includes a front-end module configured to handle mid- and high-band signals together.

Signals to be transmitted can be routed from the transceiver 509 to the PA module 510 on the appropriate front-end module 501 where the signals are amplified (or amplification is bypassed, as described herein). The signals are then routed through the multiplexer 520, filters and/or duplexers 530, and the ASM 540 before being passed to the antenna 506 for transmission. Similarly, received signals are routed from the antenna 506 through the multiplexer 504 and directed to a front-end module 501 corresponding to a particular cellular frequency band range. The signals are routed and filtered using the ASM 540 and the filters/duplexers 530 before being amplified by the LNA module 550. One or more of the front-end modules 501 can be configured to route an FDD cellular frequency band to an LNA module 555 that is separate from the front-end modules 501. Amplified received signals from the LNA module 550 and/or the LNA module 555 can then be routed to the transceiver 509.

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

One or more features of the present disclosure can be implemented with various cellular frequency bands as described herein. Examples of such bands are listed in Table 2. It will be understood that at least some of the bands can be divided into sub-bands. It will also be understood that one or more features of the present disclosure can be implemented with frequency ranges that do not have designations such as the examples of Table 2.

TABLE 2

| | | Tx Frequency | Rx Frequency |
|---|---|---|---|
| Band | Mode | Range (MHz) | Range (MHz) |
| B1 | FDD | 1,920-1,980 | 2,110-2,170 |
| B2 | FDD | 1,850-1,910 | 1,930-1,990 |
| B3 | FDD | 1,710-1,785 | 1,805-1,880 |
| B4 | FDD | 1,710-1,755 | 2,110-2,155 |
| B5 | FDD | 824-849 | 869-894 |
| B6 | FDD | 830-840 | 875-885 |
| B7 | FDD | 2,500-2,570 | 2,620-2,690 |
| B8 | FDD | 880-915 | 925-960 |
| B9 | FDD | 1,749.9-1,784.9 | 1,844.9-1,879.9 |
| B10 | FDD | 1,710-1,770 | 2,110-2,170 |
| B11 | FDD | 1,427.9-1,447.9 | 1,475.9-1,495.9 |
| B12 | FDD | 699-716 | 729-746 |
| B13 | FDD | 777-787 | 746-756 |
| B14 | FDD | 788-798 | 758-768 |
| B15 | FDD | 1,900-1,920 | 2,600-2,620 |
| B16 | FDD | 2,010-2,025 | 2,585-2,600 |
| B17 | FDD | 704-716 | 734-746 |
| B18 | FDD | 815-830 | 860-875 |
| B19 | FDD | 830-845 | 875-890 |
| B20 | FDD | 832-862 | 791-821 |
| B21 | FDD | 1,447.9-1,462.9 | 1,495.9-1,510.9 |
| B22 | FDD | 3,410-3,490 | 3,510-3,590 |
| B23 | FDD | 2,000-2,020 | 2,180-2,200 |
| B24 | FDD | 1,626.5-1,660.5 | 1,525-1,559 |
| B25 | FDD | 1,850-1,915 | 1,930-1,995 |
| B26 | FDD | 814-849 | 859-894 |
| B27 | FDD | 807-824 | 852-869 |
| B28 | FDD | 703-748 | 758-803 |
| B29 | FDD | N/A | 716-728 |
| B30 | FDD | 2,305-2,315 | 2,350-2,360 |
| B31 | FDD | 452.5-457.5 | 462.5-467.5 |
| B32 | FDD | N/A | 1,452-1,496 |
| B33 | TDD | 1,900-1,920 | 1,900-1,920 |
| B34 | TDD | 2,010-2,025 | 2,010-2,025 |
| B35 | TDD | 1,850-1,910 | 1,850-1,910 |
| B36 | TDD | 1,930-1,990 | 1,930-1,990 |
| B37 | TDD | 1,910-1,930 | 1,910-1,930 |
| B38 | TDD | 2,570-2,620 | 2,570-2,620 |
| B39 | TDD | 1,880-1,920 | 1,880-1,920 |
| B40 | TDD | 2,300-2,400 | 2,300-2,400 |
| B41 | TDD | 2,496-2,690 | 2,496-2,690 |
| B42 | TDD | 3,400-3,600 | 3,400-3,600 |
| B43 | TDD | 3,600-3,800 | 3,600-3,800 |
| B44 | TDD | 703-803 | 703-803 |
| B45 | TDD | 1,447-1,467 | 1,447-1,467 |
| B46 | TDD | 5,150-5,925 | 5,150-5,925 |
| B65 | FDD | 1,920-2,010 | 2,110-2,200 |
| B66 | FDD | 1,710-1,780 | 2,110-2,200 |
| B67 | FDD | N/A | 738-758 |
| B68 | FDD | 698-728 | 753-783 |

The principles and advantages of the embodiments described herein can be used for a wide variety of applications.

For example, various electronic devices can operate with front-end modules having acoustic wave filters with integrated phase shift circuits. For instance, a front-end module having acoustic wave filters with integrated phase shift circuits can be included in various electronic devices, including, but not limited to consumer electronic products, parts of the consumer electronic products, electronic test equipment, etc. Example electronic devices include, but are not limited to, a base station, a wireless network access point, a mobile phone (for instance, a smartphone), a tablet, a television, a computer monitor, a computer, a hand-held computer, a personal digital assistant (PDA), a microwave, a refrigerator, an automobile, a stereo system, a disc player, a digital camera, a portable memory chip, a washer, a dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “may,” “could,” “might,” “can,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While certain embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. An acoustic wave filter module, comprising:
a metal plate;
a piezoelectric substrate mounted on the metal plate;
a first surface acoustic wave filter mounted on the piezoelectric substrate and coupled between a first input and an output of the acoustic wave filter module;
at least one capacitor mounted on the piezoelectric substrate; and
at least two inductors formed on the metal plate, the at least two inductors and the at least one capacitor electrically connected to implement a π-type high pass filter coupled between the first surface acoustic wave filter and the output of the acoustic wave filter module.

2. The acoustic wave filter module of claim 1 wherein the piezoelectric substrate is a lithium tantalate or lithium niobate substrate.

3. The acoustic wave filter module of claim 2 wherein the metal plate is a copper plate.

4. The acoustic wave filter module of claim 1 wherein the π-type high pass filter induces a phase shift of a radio frequency signal filtered by the first surface acoustic wave filter.

5. The acoustic wave filter module of claim 1 wherein the at least two inductors have the same inductivity.

6. The acoustic wave filter module of claim 1 further comprising a second surface acoustic wave filter coupled in parallel to the first surface acoustic wave filter between a second input and the output of the acoustic wave filter module.

7. The acoustic wave filter module of claim 6 wherein the π-type high pass filter is configured to reduce the reflection coefficient at the output of the first surface acoustic wave filter in a passband of the second surface acoustic wave filter.

8. A multi-chip module for a mobile device, the multi-chip module comprising:
a first die including an acoustic wave filter module, the acoustic wave filter module including a metal plate, a piezoelectric substrate mounted on the metal plate, a first surface acoustic wave filter mounted on the piezoelectric substrate and coupled between a first input and an output of the acoustic wave filter module, at least one capacitor mounted on the piezoelectric substrate, and at least two inductors formed on the metal plate, the at least two inductors and the at least one capacitor electrically connected to implement a π-type high pass filter coupled between the first surface acoustic wave filter and the output of the acoustic wave filter module;
a second die including an antenna switch module coupled to the output of the acoustic wave filter module; and
a third die including a power amplifier module coupled to an input of the acoustic wave filter module.

9. The multi-chip module of claim 8 wherein the piezoelectric substrate is a lithium tantalate or lithium niobate substrate.

10. The multi-chip module of claim 9 wherein the metal plate is a copper plate.

11. The multi-chip module of claim 8 wherein the π-type high pass filter induces a phase shift of a radio frequency signal filtered by the first surface acoustic wave filter.

12. The multi-chip module of claim 8 wherein the acoustic wave filter module further includes a second surface acoustic wave filter coupled in parallel to the first surface acoustic wave filter between a second input and the output of the acoustic wave filter module.

13. The multi-chip module of claim 12 wherein the π-type high pass filter is configured to reduce the reflection coefficient at the output of the first surface acoustic wave filter in a passband of the second surface acoustic wave filter.

14. A mobile device, comprising:
an antenna configured to receive and transmit radio frequency signals;
a front end module including an antenna switch module electrically connected to an acoustic wave filter module, the acoustic wave filter module including a metal plate, a piezoelectric substrate mounted on the metal plate, a first surface acoustic wave filter mounted on the piezoelectric substrate and coupled between a first input and an output of the acoustic wave filter module, at least one capacitor mounted on the piezoelectric substrate, and at least two inductors formed on the metal plate, the at least two inductors and the at least one capacitor electrically connected to implement a π-type high pass filter coupled between the first surface acoustic wave filter and the output of the acoustic wave filter module; and
a transceiver coupled to the front end module and configured to process radio frequency signals received or transmitted by the antenna.

15. The mobile device of claim 14 wherein the front end module further includes a power amplifier module including power amplifiers configured to amplify radio frequency signals received from the transceiver.

16. The mobile device of claim 14 wherein the piezoelectric substrate is a lithium tantalate or lithium niobate substrate.

17. The mobile device of claim 16 wherein the metal plate is a copper plate.

18. The mobile device of claim 14 wherein the π-type high pass filter induces a phase shift of a radio frequency signal filtered by the first surface acoustic wave filter.

19. The mobile device of claim 14 wherein the at least two inductors have the same inductivity.

20. The mobile device of claim 14 wherein the acoustic wave filter module further includes a second surface acoustic wave filter coupled in parallel to the first surface acoustic wave filter between a second input and the output of the acoustic wave filter module.

21. The mobile device of claim 20 wherein the π-type high pass filter is configured to reduce the reflection coefficient at the output of the first surface acoustic wave filter in a passband of the second surface acoustic wave filter.
